(19) United States
(12) Patent Application Publication
(10) Pub. No.: US 2014/0191167 A1
(43) Pub. Date: Jul. 10, 2014

(54) Conductive Composition

(71) Applicant: Giga Solar Materials Corporation, Hsinchu County (TW)

(72) Inventors: Wen-Jui HUANG, Hsinchu County (TW); Pi-Yu HSIN, Hsinchu County (TW); Chih-Hsien YEH, Hsinchu County (TW)

(73) Assignee: Giga Solar Materials Corporation, Hsinchu County (TW)

(21) Appl. No.: 14/146,021

(22) Filed: Jan. 2, 2014

Related U.S. Application Data
(60) Provisional application No. 61/748,772, filed on Jan. 4, 2013.

(51) Int. Cl. H01L 31/0224

(52) U.S. Cl. CPC H01L 31/022425
USPC 252/514

(57) ABSTRACT

The present invention discloses a conductive paste for solar cell, including the following composition: (a) a silver powder; (b) a filler which can be coated with a conductor; (c) a glass frit; and further (d) a dispersing agent, an organic vehicle, and at least one additive. The filler, especially conductor coated, is used to replace part of silver powder as an ingredient of the conductive paste and thus reduces manufacturing cost without conductivity diminishing. This conductive paste can be utilized to form the front-side electrode of the substrate for solar cell.

### CROSS-REFERENCE TO RELATED APPLICATION

The application claims the benefit of U.S. Provisional Application No. 61/748,772 filed Jan. 4, 2013.

### TECHNICAL FIELD

The present invention generally relates to a conductive composition, more particularly, to a conductive composition applied to a solar cell.

### BACKGROUND

The solar cell is a semiconductor device capable of converting light energy to electricity by the photovoltaic effect. Basically, any semiconductor diode can be used to convert light energy into electrical energy. The solar cells generate electricity based on two factors of the photoconductive effect and the internal electric field. Therefore, the choice of materials of the solar cells needs to be considered its photoconductive effect and how to generate its internal electric field.

The performance of a solar cell is mainly determined by the conversion efficiency between light and electricity. The factors that would have an impact on the conversion efficiency include: the intensity and temperature of sunlight; resistance of the material and the quality and defect density of the substrate; concentration and depth of the p-n junction; surface reflectance against light; the line width, line height and contact resistance of the metal electrode. Hence, in order to produce solar cells with high conversion efficiency, tight control towards each of the impact factors mentioned above is necessary.

For example, the front-side silver paste of the conductive composition accounts for more than 50% of the cost of the solar cells. In recent years, it usually performs a front-side silver paste thinning and electroplating process to reduce the amount of use of the silver in order to reduce the production cost of the solar cells.

The purpose of the present patent is to the use of alumina and alumina surface silver to reduce the cost of the conductive silver paste.

### SUMMARY

In the present invention, a front-side conductive paste (conductive composition) is provided, which comprises: (a) a silver powder, (b) a filler, which can be coated with a conductor, (c) a glass frit, and (d) a binder (organic vehicle). The filler, especially conductor coated, is used to replace part of silver powder as an ingredient of the conductive paste and thus reduces manufacturing cost without conductivity diminishing. For an even lower cost, the conductor coating can be only on part of the surface of filler, and coated filler can be mixed with uncoated one. To achieve this particular purpose, the filler shares 2˜20 wt % of the total solids content in the conductive composition, besides 74˜92 wt % silver powder and 2˜6 wt % glass frit. In one example of this invention, a dispersing agent may be included in the front-side conductive paste. Particle size (grain size) of filler is 0.1 um˜10 um (micron). The glass frit may further comprise Pb, Si, B, Al, Zn, Sn, F, Li, Ti, Te, Ag, Na, K, Rb, Cs, Ge, Ga, In, Ni, Ca, Mg, Sr, Ba, Se, Mo, W, Y, As, La, Nd, Co, Gd, Eu, Ho, Yb, Lu, Bi, Ta, V, Zr, Mn, P, Cu, Ce, Nb, or a combination thereof. Furthermore, the glass frit is for example a lead glass frit.

According to an aspect, the front-side conductive paste may further include, an organic vehicle and at least one additive. Also, the filler includes an alloy or metal oxide, wherein a material of the filler includes aluminum oxide, zirconium oxide, silicon oxide, zinc oxide, cupric oxide or a combination thereof. The coating may be a metal, a non-metal, or an alloy which is electric conductive.

According to another aspect, the at least one additive is selected from the group consisting of ZrO₂, V₂O₅, Ag₂O, Er₂O₃, SnO, MgO, Nd₂O₃, TiO₂, SeO₂, PbO, Cr₂O₃, K₂O, P₂O₅, MnO₂, NiO, Sm₂O₃, GeO₂, ZnF₂, In₂O₃, Ga₂O₃, and the derivative thereof. The organic vehicle includes diethylene glycol monobutyl ether, ethyl cellulose or hydrogenated castor oil.

### BRIEF DESCRIPTION OF THE DRAWINGS

The components, characteristics and advantages of the present invention may be understood by the detailed descriptions of the preferred embodiments outlined in the specification.

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

References in the specification to “one embodiment” or “an embodiment” refers to a particular feature, structure, or characteristic described in connection with the preferred embodiments is included in at least one embodiment of the present invention. Therefore, the various appearances of “in one embodiment” or “in an embodiment” do not necessarily refer to the same embodiment. Moreover, the particular feature, structure or characteristic of the invention may be appropriately combined in one or more preferred embodiments.

In general, a silicon wafer solar cell includes a first electrode, a second electrode and a P-N semiconductor layer; the two electrodes are electrically conductive. The P-N semiconductor layer is configured on a first surface of the first electrode. The first electrode (known as a working electrode or a semiconductor electrode) includes any materials with electrical conductivity. For example, the first electrode may be formed by a glass, organic vehicle, silver powder. The second electrode (known as a back electrode) also includes any materials with electrical conductivity. The second electrode includes a conductive substrate which may be formed by a glass, organic vehicle, silver powder.

It should be noted that a conductive composition of the present invention can be applied to the front-side or back-side of any type silicon wafer solar cells. In other words, the disclosed conductive composition can be applied to the positive electrode or the back electrode.

In the present invention, a front-side conductive paste (conductive composition) is provided, which comprises: (a) a silver powder, (b) an alumina, which can be coated with silver, (c) a glass fit, and (d) a binder (organic vehicle). Normally, a dispersing agent may be included in the front-side conductive paste. Particle size (grain size) of alumina is 0.1 um˜10 um (micron). The glass fit may further comprise Pb, Si, B, Al, Zn, Sn, F, Li, Ti, Te, Ag, Na, K, Rb, Cs, Ge, Ga, In, Ni, Ca, Mg, Sr, Ba, Se, Mo, W, Y, As, La, Nd, Co, Gd, Eu, Ho, Yb, Lu, Bi, Ta, V, Zr, Mn, P, Cu, Ce, Nb, or the combination thereof. The glass fit is for example a lead glass fit.

In one embodiment, a filler may be added into the front-side conductive paste. The filler may be a metal oxide, and the metal is as a main body to enhance adhesion. A conductive coating portion may be optionally covering substantially at least a partial surface of the filler, wherein the coating portion includes at least metal or alloy to enhance conductivity.

A solar cell element is further provided, which includes an electrode or wire formed by coating the conductive paste composition on a silicon semiconductor substrate and drying and sintering it. The dispersing agent contained in the conductive paste composition of the present invention has good moisture resistance and is capable of effectively addressing the warping problem of a solar cell and improving the adhesion between the backside conductive paste and the silver paste of the solar cell.

Whichever, for the front-side electrode example, the present invention discloses a conductive composition, which may be applied to be as material of the front-side electrode and manufacturing method thereof. The conductive composition comprises a metal filler and the metal functions as to support the main body, which is silver in this invention, to enhance the adhesion. A coating portion may cover substantially at least a partial surface of the filler, wherein the coating portion includes at least metal or alloy to improve the conductivity.

Moreover, cost of the material of the filler and the coating portion can be lower than that of the main body to achieve low-cost materials to replace high-cost core with efficacy of increasing adhesion and nearly equal conductivity.

The filler with conductor coated thereon, silver particles, a melting glass (glass frit) and additives are added into an organic vehicle. The organic vehicle can be employed to improve the dispersion of the filler and the silver particles, and further increase the adhesion to the substrate. In an embodiment, the organic vehicle includes diethylene glycol monobutyl ether, ethyl cellulose or hydrogenated castor oil. In one embodiment, the additive is selected the group consisting of ZrO₂, V₂O₅, Ag₂O, Er₂O₃, SnO, MgO, Nd₂O₃, TiO₂, SeO₂, PbO, Cr₂O₃, K₂O, P₂O₅, MnO₂, NiO, Sm₂O₃, GeO₂, ZnF₂, In₂O₃, Ga₂O₃, and the derivative thereof.

The conductive composition of the present invention is prepared by adding metal oxides as the filler. The surface of the filler is preferably coating a conductive layer, such as metal, alloy and the combination thereof. The material of the filler is, for instance, alumina (aluminum oxide), zirconium oxide, silicon oxide, zinc oxide, cupric oxide and the combination thereof. The filler is performed by a surface modification, and its surface is coated with a silver or copper metal layer to achieve the purpose of increasing adhesion, and thus increasing the peeling strength between silver-silver interface, and increasing the peeling strength between silver-glass interface; and thereby achieving the purpose of cost reduction.

The formed conductive composition can be performed by a screen printing process to form a conductive film. The silver paste is utilized by a screen printing to print on the front side of the silicon substrate of a solar cell.

### Embodiment 1

| | Weight % | Weight % | Weight % | Weight % | Median | Median | |
|---|---|---|---|---|---|---|---|
| | of solid | of solid | of solid | of solid | Series | Fill | Median |
| EX | Ag | Al₂O₃ | Glass 1 | Glass 2 | Resistivity (Ω) | Factor (%) | efficiency (%) |
| 1 | 95.5 | 0 | 4.5 | | 2.5 | 79.3 | 17.55 |
| 2 | 95.5 | 0 | | 4.5 | 3.1 | 78.6 | 17.41 |
| 3 | 94.4 | 1.1 | 4.5 | | 2.5 | 79.1 | 17.53 |
| 4 | 93.3 | 2.2 | 4.5 | | 2.5 | 79.1 | 17.52 |
| 5 | 91.1 | 4.4 | 4.5 | | 2.7 | 79.0 | 17.50 |
| 6 | 85 | 10.5 | 4.5 | | 2.9 | 78.8 | 17.41 |
| 7 | 82.7 | 12.8 | 4.5 | | 3.1 | 78.6 | 17.38 |
| 8 | 80.6 | 14.9 | 4.5 | | 3.4 | 78.5 | 17.35 |

### Embodiment 2

| | Weigh % | Weight % | Weight % | Weight % | Median | Median | |
|---|---|---|---|---|---|---|---|
| | of solid | of solid | of solid | of solid | Series | Fill | Median |
| EX | Ag | AgAl₂O₃ | Glass 1 | Glass 2 | Resistivity (Ω) | Factor (%) | efficiency (%) |
| 1 | 95.5 | 0 | 4.5 | | 2.5 | 79.3 | 17.55 |
| 2 | 95.5 | 0 | | 4.5 | 3.1 | 78.6 | 17.41 |
| 9 | 85 | 10.5 | 4.5 | | 2.5 | 79.1 | 17.46 |
| 10 | 80.6 | 14.9 | 4.5 | | 2.7 | 78.9 | 17.40 |

In the embodiments 1 and 2, they indicate that the front-side conductive paste comprises Ag/Al₂O₃/Glass 1/Glass 2 (Ag/AgAl₂O₃/Glass 1/Glass 2) with various solid contents, respectively.

From above-mentioned, in the present invention, the filler, for example, Alumina (or zirconium oxide, silicon oxide, zinc oxide), may be adequately added into the conductive composition to enhance the adhesion and avoid the section of the original silver layer such that the conductive composition has a pretty good electrical conductivity, and similar low resistance as the ordinary silver paste.

An embodiment is an implementation or example of the present invention. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. It should be appreciated that in the foregoing description of exemplary embodiments of the present invention, various features are sometimes grouped together in a single embodiment, figure, or description thereof for the purpose of streamlining the disclosure and aiding in the understanding of one or more of the various inventive aspects. This composition of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims are hereby expressly incorporated into this description, with each claim standing on its own as a separate embodiment of this invention.

What is claimed is:

1. A conductive paste, comprising:
a silver powder;
a filler, which can be coated with a conductor on at least part of surface; and
a glass frit;
wherein a total solids content of said conductive paste comprises 74˜92 wt % the silver powder, 2˜20 wt % the filler, and 2˜6 wt % the glass fit.

2. The conductive paste of claim 1, which further comprises an organic vehicle, a dispersing agent, and at least one additive.

3. The conductive paste of claim 1, wherein said glass frit is a lead glass frit.

4. The conductive paste of claim 1, wherein said glass frit further includes at least one element consisting of: Pb, Si, B, Zn, Sn, F, Li, Ti, Te, Ag, Na, K, Rb, Cs, Ge, Ga, In, Ni, Ca, Mg, Sr, Ba, Se, Mo, W, Y, As, La, Nd, Co, Gd, Eu, Ho, Yb, Lu, Bi, Ta, V, Zr, Mn, P, Cu, Ce, Nb, or a combination thereof.

5. The conductive paste of claim 1, wherein said filler includes an alloy or metal oxide, and wherein said conductor includes a metal, a non-metal, or an alloy which is electric conductive.

6. The conductive paste of claim 1, wherein a material of said filler includes aluminum oxide, zirconium oxide, silicon oxide, zinc oxide, cupric oxide or a combination thereof, and wherein said conductor includes silver or copper.

7. The conductive paste of claim 2, wherein said at least one additive is selected from the group consisting of ZrO₂, V₂O₅, Ag₂O, Er₂O₃, SnO, MgO, Nd₂O₃, TiO₂, SeO₂, PbO, Cr₂O₃, K₂O, P₂O₅, MnO₂, NiO, Sm₂O₃, GeO₂, ZnF₂, In₂O₃, Ga₂O₃, and the derivative thereof.

8. The conductive paste of claim 1, wherein the average grain size of said filler is approximately 0.1˜10 micron

9. The conductive paste of claim 2, wherein said glass frit further includes at least one element consisting of: Pb, Si, B, Zn, Sn, F, Li, Ti, Te, Ag, Na, K, Rb, Cs, Ge, Ga, In, Ni, Ca, Mg, Sr, Ba, Se, Mo, W, Y, As, La, Nd, Co, Gd, Eu, Ho, Yb, Lu, Bi, Ta, V, Zr, Mn, P, Cu, Ce, Nb, or a combination thereof.

10. The conductive paste of claim 2, wherein said organic vehicle includes diethylene glycol monobutyl ether, ethyl cellulose or hydrogenated castor oil.

11. A conductive paste for a solar cell, said conductive paste comprising:
a silver powder;
a filler, which can be coated with a conductor on at least part of surface; and
a glass frit,
wherein a total solids content of said conductive paste comprises 74˜92 wt % the silver powder, 2˜20 wt % the filler, and 2˜6 wt % the glass frit.

12. The conductive paste of claim 11, which further comprises an organic vehicle, a dispersing agent, and at least one additive.

13. The conductive paste of claim 11, wherein said glass frit is a lead glass frit.

14. The conductive paste of claim 11, wherein said glass frit further includes at least one element consisting of: Pb, Si, B, Zn, Sn, F, Li, Ti, Te, Ag, Na, K, Rb, Cs, Ge, Ga, In, Ni, Ca, Mg, Sr, Ba, Se, Mo, W, Y, As, La, Nd, Co, Gd, Eu, Ho, Yb, Lu, Bi, Ta, V, Zr, Mn, P, Cu, Ce, Nb, or a combination thereof.

15. The conductive paste of claim 11, wherein said filler includes an alloy or metal oxide, and wherein said conductor includes a metal, a non-metal, or an alloy which is electric conductive.

16. The conductive paste of claim 11, wherein a material of said filler includes aluminum oxide, zirconium oxide, silicon oxide, zinc oxide, cupric oxide or a combination thereof, and wherein said conductor includes silver or copper.

17. The conductive paste of claim 12, wherein said at least one additive is selected from the group consisting of ZrO₂, V₂O₅, Ag₂O, Er₂O₃, SnO, MgO, Nd₂O₃, TiO₂, SeO₂, PbO, Cr₂O₃, K₂O, P₂O₅, MnO₂, NiO, Sm₂O₃, GeO₂, ZnF₂, In₂O₃, Ga₂O₃, and the derivative thereof.

18. The conductive paste of claim 12, wherein the average grain size of said filler is approximately 0.1˜10 micron.

19. The conductive paste of claim 12, wherein said glass frit further includes at least one element consisting of: Pb, Si, B, Zn, Sn, F, Li, Ti, Te, Ag, Na, K, Rb, Cs, Ge, Ga, In, Ni, Ca, Mg, Sr, Ba, Se, Mo, W, Y, As, La, Nd, Co, Gd, Eu, Ho, Yb, Lu, Bi, Ta, V, Zr, Mn, P, Cu, Ce, Nb, or a combination thereof.

20. The conductive paste of claim 12, wherein said organic vehicle includes diethylene glycol monobutyl ether, ethyl cellulose or hydrogenated castor oil.
